(19) United States
(12) Patent Application Publication
(10) Pub. No.: US 2026/0163571 A1
(43) Pub. Date: Jun. 11, 2026

(54) DRIVE CIRCUIT

(71) Applicant: RENESAS ELECTRONICS CORPORATION, Tokyo (JP)

(72) Inventors: Asaki MIZUTA, Tokyo (JP); Takeshi YOSHIZAWA, Tokyo (JP)

(21) Appl. No.: 19/413,246

(22) Filed: Dec. 9, 2025

(30) Foreign Application Priority Data
Dec. 11, 2024 (JP) 2024-216219

(51) Int. Cl. H03K 17/56; H03F 3/45; H03K 5/24

(52) U.S. Cl. CPC H03K 17/56; H03F 3/45475; H03F 2203/45151; H03K 5/24

(57) ABSTRACT

A drive circuit can calculate an optimal phase adjustment amount by passing a current through an external load. The drive circuit includes a control circuit that outputs a first AC signal and a second AC signal from an AC signal source, and a reference voltage generation circuit that has a differential amplifier generating a first AC voltage from the first AC signal and outputs the first AC voltage to one end of an external load. It also includes a voltage-current conversion circuit that supplies an AC current to the external load from the second AC signal, and a comparator connected across both ends of the external load. The comparator compares the first AC voltage at one end of the external load with the second AC voltage at the other end of the external load and changes the output voltage when the first and second AC voltages are inverted.

### CROSS-REFERENCE TO RELATED APPLICATIONS

The disclosure of Japanese Patent Application No. 2024-216219 filed on Dec. 11, 2024, including the specification, drawings and abstract is incorporated herein by reference in its entirety.

### BACKGROUND

This disclosure relates to a driving circuit. There are disclosed techniques listed below.

[Patent Document 1] Japanese Unexamined Patent Application Publication No. 2015-156599

Patent Document 1 discloses a drive circuit that drives a connected load equipped with a phase adjuster. The phase adjuster can perform phase adjustment by monitoring the output voltage (V22) from the voltage-current conversion circuit 2.

### SUMMARY

The phase adjustment in Patent Document 1 describes a mechanism that allows adjustment through exhaustive search. However, an efficient phase adjustment method is not considered. Therefore, during testing/evaluation for shipment, phase adjustment must be performed through exhaustive Search. Furthermore, since the load (such as a sensor with impedance against frequency) changes with each device, phase adjustment is required for each device development, resulting in a significant amount of adjustment work.

This disclosure has been made to solve such problems and aims to provide a device and method capable of efficiently adjusting the phase. Other objects and novel features will become apparent from the description of this specification and the accompanying drawings.

The drive circuit according to this disclosure includes an AC signal source, a control circuit that outputs a first AC signal and a second AC signal from the AC signal source, and a reference voltage generation circuit that has a differential amplifier generating a first AC voltage of constant amplitude from the first AC signal and outputs the first AC voltage to one end of an external load. The reference voltage generation circuit includes a first resistor with one end connected to a predetermined voltage and the other end connected to the first input terminal of the differential amplifier, and a second resistor with one end connected to the first input terminal of the differential amplifier and the other end connected to the output terminal of the differential amplifier. The reference voltage generation circuit receives the first AC signal at the second input terminal of the differential amplifier, and the first AC voltage is output from the output terminal of the differential amplifier. The drive circuit also includes a comparator connected to the other end of the external load, a voltage-current conversion circuit that supplies an AC current of constant amplitude to the external load from the second AC signal, and a comparator that compares the first AC voltage at one end of the external load with the second AC voltage at the other end of the external load and changes the output voltage when the first AC voltage and the second AC voltage are inverted. The control circuit calculates the phase adjustment amount of the second AC signal relative to the first AC signal so that the first AC voltage and the second AC voltage become out of phase based on the change in output voltage from the comparator.

According to this disclosure, it is possible to provide a drive circuit that can find the optimal phase adjustment amount by passing current through the external load.

### BRIEF DESCRIPTION OF THE DRAWINGS

FIG. 1 is a circuit diagram showing the configuration of a drive circuit according to the first embodiment.

FIG. 2 is a graph explaining an example of phase adjustment based on the voltage difference between the reference voltage and the load.

FIG. 3 is a diagram showing an AC waveform before phase adjustment.

FIG. 4 is a diagram showing an AC waveform after phase adjustment.

FIG. 5 is a diagram showing another example of an AC waveform before phase adjustment.

FIG. 6 is a diagram showing another example of an AC waveform after phase adjustment.

FIG. 7 is a circuit diagram showing the configuration of a drive circuit according to the second embodiment.

### DETAILED DESCRIPTION

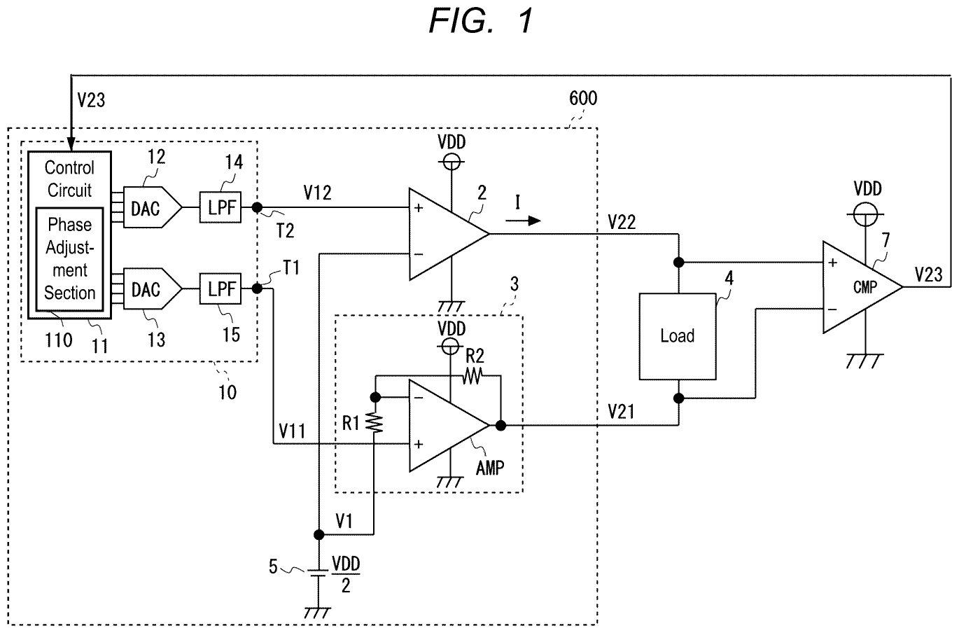

A preferred embodiment of the present invention will be described with reference to the accompanying drawings. FIG. 1 is a circuit diagram showing the configuration of a drive circuit according to the first embodiment. The drive circuit 600 includes a phase adjustment unit 110 that imparts a phase adjustment function to the AC voltage signal source 10.

It is also possible to monitor the amplitude of the voltage V22 at one end of load 4 and perform phase adjustment so that the voltage V22 and the voltage V21 become out of phase based on the amplitude of the voltage V22. In contrast, in this disclosure, the point at which the voltages V22 and V21 reverse (zero-cross) is identified from the voltage difference V22−V21 between the loads (e. g., sensors), and then the amount of phase adjustment is calculated so that the voltage difference V22−V21 and the voltage V21 become out of phase.

The optimal phase adjustment amount can be calculated using either the voltage V22 or the voltage difference V22−V21. When using voltage V22, the phase of voltage V22 changes depending on the setting (phase adjustment amount) of the phase adjuster, so information on the phase adjustment amount is required in addition to the voltage V22 when finding the optimal phase adjustment amount.

On the other hand, when using the voltage difference V22−V21, the phase of the voltage difference V22−V21 is uniquely determined by the phase of the current output by the voltage-current conversion circuit and the impedance of the load, so it does not depend on the setting of the phase adjuster. In other words, the optimal phase adjustment amount can be found using only the information obtained from the voltage difference V22−V21. Therefore, adjusting the phase from the voltage difference V22−V21 allows for pure phase calculation without the influence of other factors due to the characteristics of the circuit configuration.

Accordingly, in this disclosure, comparator 7 monitors the voltage difference V22−V21 across load 4, identifies the point at which the voltages V22 and V21 reverse, and thereby calculates a phase adjustment amount such that the voltage difference V22−V21 and the voltage V21 are in opposite phases. Control circuit 11 adjusts the phase of the AC voltage signal V11 relative to the AC voltage signal V12 based on this phase adjustment amount.

The drive circuit 600 according to the first embodiment will be specifically described below. The AC voltage signal source 10 outputs an AC voltage signal V11 (also referred to as the first AC voltage signal) to the reference voltage generation circuit 3 and outputs an AC voltage signal V12 (also referred to as the second AC voltage signal) to the voltage-current conversion circuit 2. The AC voltage signal V11 is a voltage in the form of a sine wave with a constant amplitude. The AC voltage signal V12 is a voltage in the form of a sine wave with a constant amplitude. One terminal T1 of the AC voltage signal source 10 is connected to the non-inverting (positive phase) input terminal indicated by the plus of the reference voltage generation circuit 3. The other terminal T2 of the AC voltage signal source 10 is connected to the non-inverting (positive phase) input terminal indicated by the plus of the voltage-current conversion circuit 2. Here, the voltage output from terminal T1 is referred to as the AC voltage signal V11, and the voltage output from terminal T2 is referred to as the AC voltage signal V12.

The voltage-current conversion circuit 2 is a circuit that outputs a current signal (i.e., an in-phase current signal) proportional to the input AC voltage signal V12 to the load 4. The positive phase input terminal of the voltage-current conversion circuit 2 is connected to the terminal T2 of the AC voltage signal source 10. A DC power supply 5 that outputs a DC voltage V1 (also referred to as a predetermined voltage) of magnitude VDD/2 is inserted between the inverting input terminal of the voltage-current conversion circuit 2 and the ground. The inverting input terminal of the voltage-current conversion circuit 2 is connected to the high voltage side terminal of the DC power supply 5. The output terminal of the voltage-current conversion circuit 2 is connected to one end of load 4. Since the voltage-current conversion circuit 2 outputs a current signal in phase with the AC signal V12, the output voltage V22 (also referred to as the second AC voltage) of the voltage-current conversion circuit 2 is in phase with the AC voltage signal V12. The voltage-current conversion circuit 2 receives power supply by being inserted between the power supply voltage VDD and the ground.

The reference voltage generation circuit 3 generates a reference voltage V21 (also referred to as the first AC voltage) for supplying current to load 4. In this example, the reference voltage generation circuit 3 is configured as a non-inverting amplifier. The AC voltage signal V11 from the AC voltage signal source 10 is input to the positive phase input terminal of the reference voltage generation circuit 3. A DC power supply 5 that outputs a DC voltage V1 (also referred to as a predetermined voltage) of magnitude VDD/2 and a resistor R1 are inserted between the inverting input terminal of the reference voltage generation circuit 3 and the ground. The DC voltage V1 is input to the inverting input terminal of the reference voltage generation circuit 3. A resistor R2 is inserted between the inverting input terminal and the output terminal of the reference voltage generation circuit 3. The output terminal the reference voltage generation circuit 3 is connected to the other end of load 4. The reference voltage generation circuit 3 receives power supply by being inserted between the power supply voltage VDD and the ground.

In this example, the AC voltage signal V12 is input to the positive phase input terminal of the voltage-current conversion circuit 2, and the DC voltage V1 is input to the inverting input terminal. DC voltage V1 is input to the positive phase input terminal of the reference voltage generation circuit 3, and the AC voltage signal V11 is input to the inverting input terminal. As a result, if the load 4 is a resistor or the like and the voltage phase of V22 does not change, and the AC voltage signal V12 and the AC voltage signal V11 are phase-adjusted to be in opposite phases, the reference voltage V21 output by the reference voltage generation circuit 3 becomes an AC voltage in opposite phase to the output voltage V22 of the voltage-current conversion circuit 2.

In other embodiments, the reference voltage generation circuit 3 may be configured as an inverting amplifier, and an in-phase AC signal with respect to the AC voltage signal V12 may be input to the input terminal of the reference voltage generation circuit 3. Furthermore, the reference voltage generation circuit 3 can have other configurations as long as it can output a reference voltage in opposite phase to the output voltage of the voltage-current conversion circuit 2.

The AC voltage signal source 10 includes a control circuit 11, digital-to-analog converters (DAC) 12 and 13, and low-pass filters (LPF) 14 and 15. The control circuit 11 includes a phase adjustment section 110.

The control circuit 11 outputs digital signals to DAC12 and DAC13 to control their operations. The pattern of digital signals to DAC12 and DAC13 is stored as an array in the control circuit 11. DAC12 and 13 convert the input digital signals into analog signals to output AC voltages. The AC voltage output from DAC12 has its high-frequency components removed by LPF14 and is output as the AC signal V12 from terminal T2. The AC voltage output from DAC13 has its high-frequency components removed by LPF15 and is output as the AC signal V11 from terminal T1.

For example, the control circuit 11 can delay the digital signal given to DAC13 relative to the digital signal given to DAC12 by the phase adjustment section 110, thereby delaying the phase of the AC voltage signal V11 compared to the AC voltage signal V12. Additionally, the control circuit 11 can advance the phase of the AC voltage signal V11 compared to the AC voltage signal V12 by advancing the digital signal given to DAC13 relative to the digital signal given to DAC12 by the phase adjustment section 110.

The AC voltage signal source 10 can be applied to drive circuits according to other embodiments besides the drive circuit 600.

Comparator 7 is provided across load 4 and compares the voltage across the load, and when the voltages V22 and V21 reverse (zero-cross), it can change the output voltage V23, which is a pulse voltage, from high (H) to low (L) or from low (L) to high (H). Comparator 7 outputs this output voltage V23 to the control circuit 11 of the AC voltage signal source 10. Comparator 7 receives power supply by being inserted between the power supply voltage VDD and the ground.

When the control circuit 11 receives a signal indicating that the output voltage V23 of the comparator 7 changes, it records the sequence number of the digital signal input to DAC12. The control circuit 11 calculates the sequence number (i.e., phase adjustment amount) for delaying/advancing the digital signal input to DAC13 from the recorded sequence number of the digital signal for DAC12.

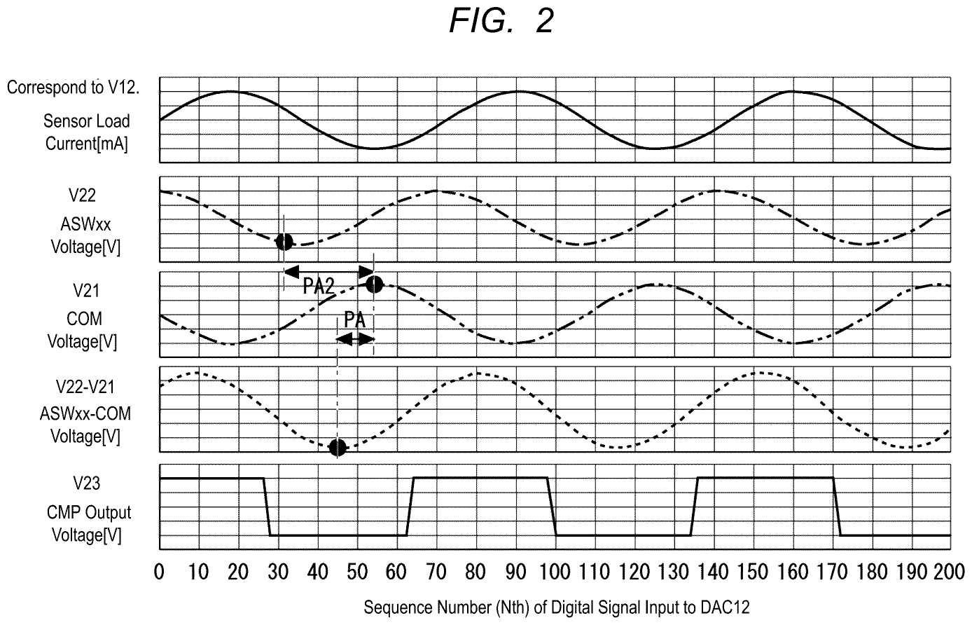

FIG. 2 is a graph explaining an example of phase adjustment based on the voltage difference between the reference voltage and the load. The horizontal axis of the graph corresponds to time, specifically indicating the sequence number (Nth) of the digital signal input to DAC12 by the control circuit 11.

The control circuit 11 controls the phase adjustment so that the reference voltage V21 is in opposite phase to the output voltage V22. As shown in FIG. 2, it is optimal for the voltages V22 and V21 to be in opposite phase, which means that the voltage difference V22−V21 and the voltage V21 being in opposite phase is the optimal phase adjustment.

To explain the meaning mathematically, when V22=Asin2πft (A is the amplitude and is a positive value) and V21 is in opposite phase, V21=Bsin (2πft-180°)=−Bsin2πft (B is the amplitude and is a positive value). In this case, V22−V21 becomes V22−V21=Asin2πft−(−Bsin2πft)=(A+B) sin2nπft. V22−V21 is in opposite phase to V21 and in phase with V22. In other words, when V22 and V21 are in opposite phase, V22−V21 and V21 are also in opposite phase. Therefore, adjusting V22−V21 to be in opposite phase to V21 has the same effect as adjusting V22 to be in opposite phase to V21.

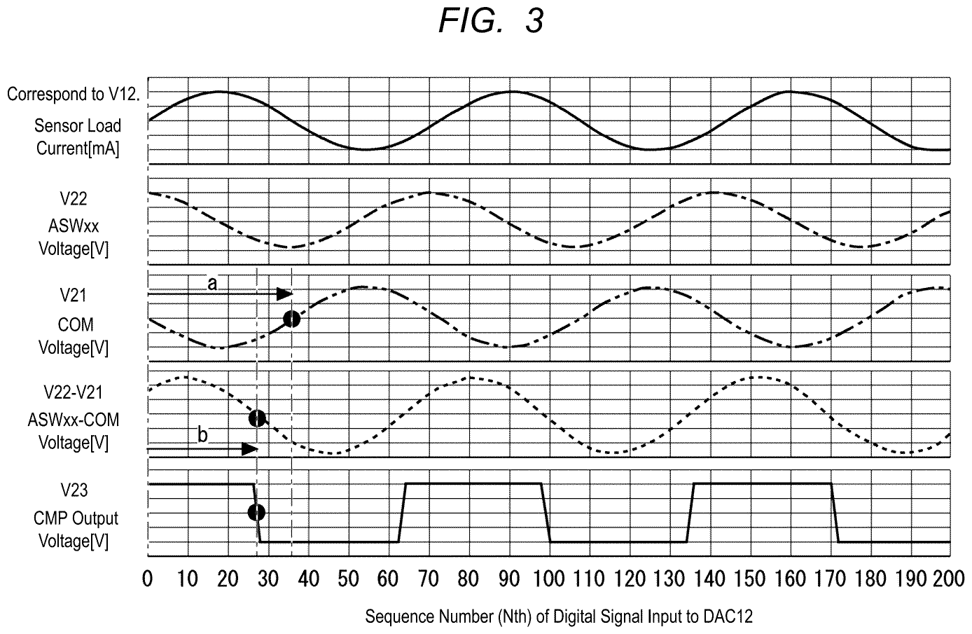

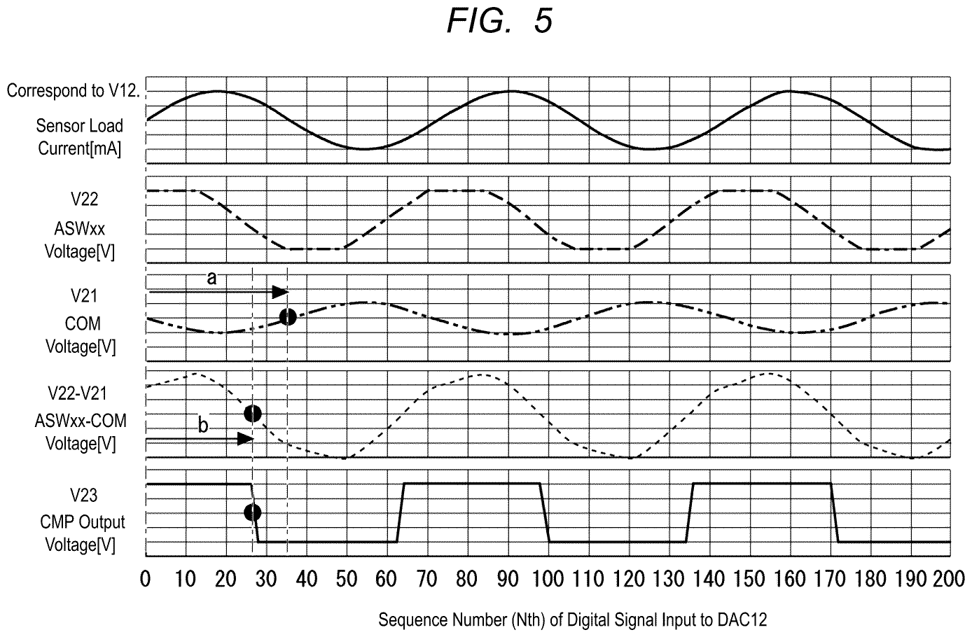

With reference to FIGS. 3 to 6, an example of calculating the phase adjustment amount will be described. One cycle of AC amplitude is composed of a sequence of 72 steps of a DAC. FIG. 3 is a diagram showing the AC waveform before phase adjustment. The a in the AC waveform of V21 shown in FIG. 3 is the phase of V21 with respect to V12 and is a known value (this is an arbitrary value (see FIG. 5), and in this example, V21 is 36 steps behind V12).

The b in the AC waveform of V22−V21 shown in FIG. 3 is the time when the sine wave becomes zero, indicating the timing when V23 becomes H→L with respect to V12 (i.e., the timing when V22 and V21 are reversed). For example, if b is 27 steps, then V22−V21 is 9 steps ahead of V12 (36 steps of half cycle—27 steps=9 steps).

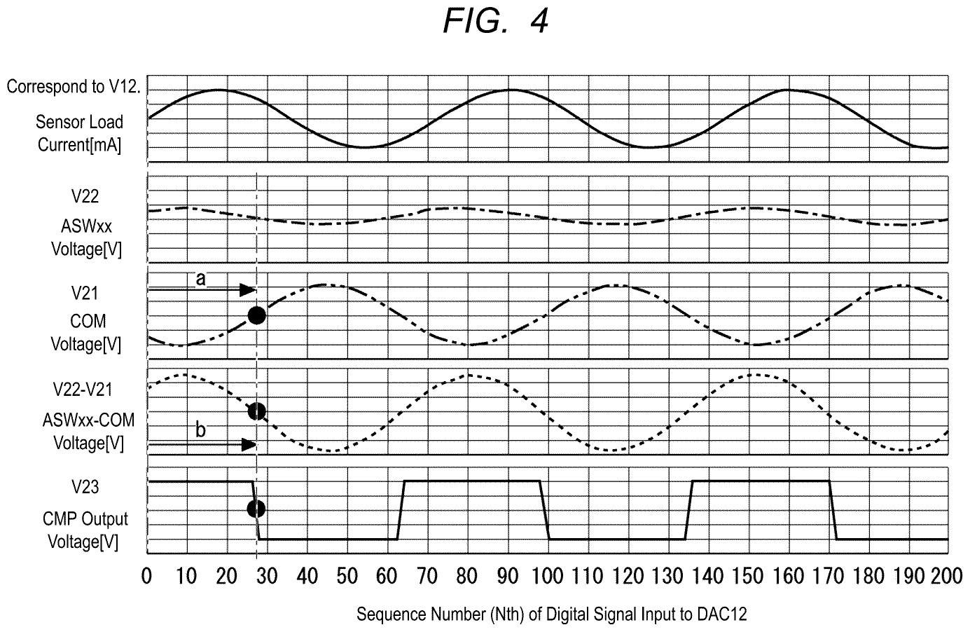

Therefore, by matching a to b (a=b), V22−V21 and V21 can be made opposite in phase. The control circuit 11 should delay the digital signal (V21) input to DAC 13 by 36 steps (opposite phase)−9 steps=27 steps with respect to the digital signal (V12) input to DAC12. In other words, the control circuit 11 should delay the digital signal (V21) input to DAC13 by the sequence of DAC at the timing when V23 becomes H→L (27 steps) with respect to the digital signal (V12) input to DAC12. FIG. 4 is a diagram showing the AC waveform after phase adjustment. In FIG. 4, the phase of V21 with respect to V 12 is delayed by 27 steps from FIG. 3. As a result, a=b, and it can be seen that V22 and V21 are in opposite phase, and V22−V21 and V21 are also in opposite phase.

In the above example, the phase adjustment amount is calculated at the first H→L timing, but it may be calculated at the L→H timing. Also, to stabilize the waveform, the phase adjustment amount may be calculated at the switching timing of any number of times (for example, the 10th time). Furthermore, in other embodiments, the phase adjustment amount may be calculated for each switching timing (H→L, L→H) multiple times, and these may be averaged to determine the phase adjustment amount.

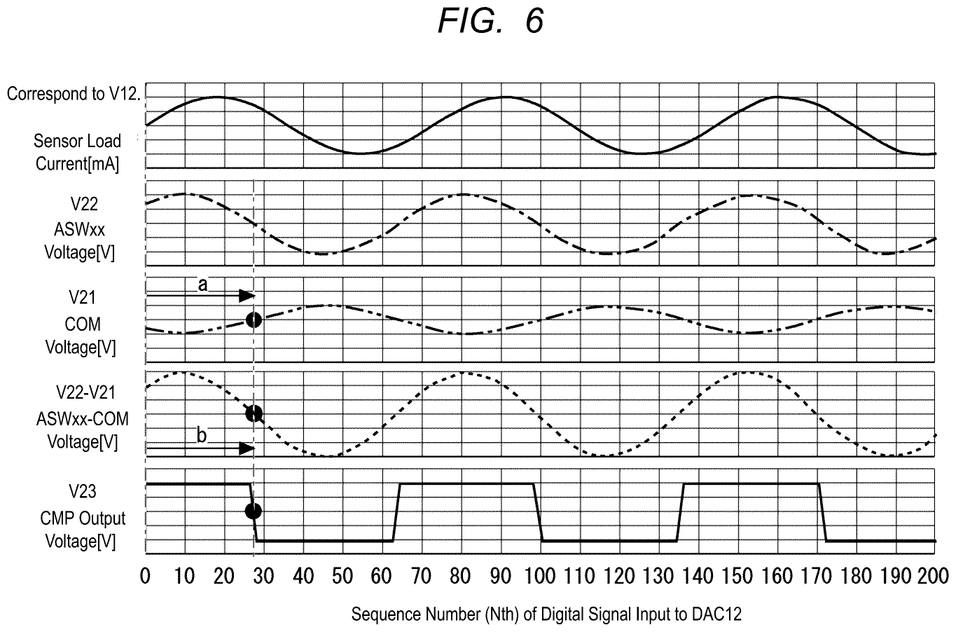

FIG. 5 is a diagram showing another example of the AC waveform before phase adjustment. The output voltage of the voltage-current conversion circuit 2 (i.e., V22) cannot be made larger than the power supply voltage and cannot be made smaller than the ground (0V). If the phase adjustment is insufficient, the voltage-current conversion circuit 2 may not be able to flow the intended AC current signal, and the voltage of V22 may clip and not become a sine wave. However, as shown in FIG. 5, even if the voltage of V22 clips and the AC waveform does not become a sine wave, phase adjustment is possible as long as it does not affect the waveform near the inversion (zero-cross) of V22 and V21. FIG. 6 is a diagram showing another example of the AC waveform after phase adjustment. In FIG. 6, a=b, and V22 and V21 are in opposite phase, and V22−V21 and V21 are in opposite phase. From the above, it can be said that the phase of V21 with respect to V12 may be any value before phase adjustment.

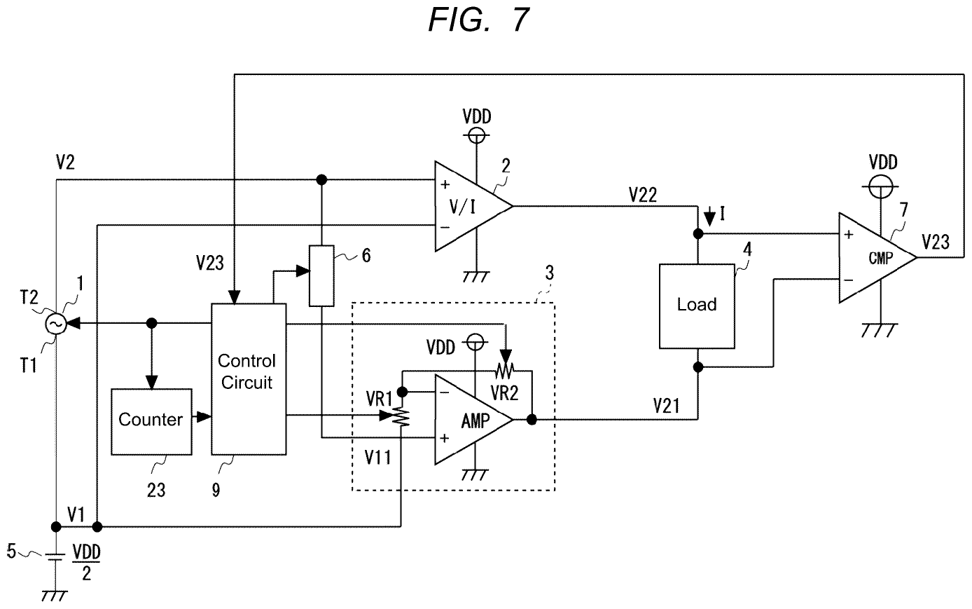

FIG. 7 is a circuit diagram showing the configuration of a drive circuit according to the second embodiment. The drive circuit 700 has a configuration in which the resistors R1 and R2 of the reference voltage generation circuit 3 in the drive circuit 600 shown in FIG. 1 are replaced with variable resistors VR1 and VR2, respectively, and a control circuit 9 is added. Control circuit 9 is configured, for example, with a digital circuit and can control the resistance values of the variable resistors VR1 and VR2. The control circuit 9 not only controls the resistance values of the variable resistors VR1 and VR2 but also controls the phase adjustment amount of the phase adjuster

In other embodiments, one or both of the first resistor R1 and the second resistor R2 may be variable resistors. The control circuit 9 may control the resistance values of one or both of the first resistor R1 and the second resistor R2.

The AC voltage signal source 1 outputs an AC voltage signal. One terminal T2 of the AC voltage signal source 1 is connected to the in-phase input terminal of the voltage-current conversion circuit 2, and the other terminal T1 is connected to the DC power supply 5. A DC power supply 5 that outputs a DC voltage V1 (also referred to as a predetermined voltage) of the size VDD/2 is inserted between the terminal T1 of the AC voltage signal source 1 and the ground. The high voltage side terminal of the DC power supply 5 is connected to terminal T1 of the AC voltage signal source 1, and the low voltage side terminal is connected to the ground. Here, the voltage output from terminal T1 is referred to as DC voltage V1, and the voltage output from terminal T2 is referred to as AC signal V2. The AC signal after phase adjustment is referred to as V11. Also, counter 23 is connected to the AC voltage signal source 1 and the control circuit 9.

The control circuit 9 can instruct the start and end of the operation of the AC voltage signal source 1 and counter 23. Comparator 7, connected across load 4, can compare the voltage across load 4. The comparator 7 changes the output voltage V23 from H to L or from L to H when V22 and V21 are reversed (zero-cross). The control circuit 9 measures the timing of the AC signal with counter 23. The control circuit 9 receives the timing when the output voltage V23 from the comparator 7 changes (from H to L) and latches and acquires the value of counter 23. The control circuit 9 sets the phase adjuster 6 so that the voltage signal of V21 is delayed by the value of the counter. This allows the phase to be adjusted so that V22−V21 and V21 are in opposite phase.

The present disclosure is provided as the following drive circuit. That is, the drive circuit (600, 700) includes an AC signal source (1, 10) and a control circuit (11, 9) that outputs a first AC signal (V11) and a second AC signal (V12, V2) from the AC signal source, and has a differential amplifier that generates a first AC voltage (V21) of constant amplitude from the first AC signal (V11, V1), and a reference voltage generation circuit (3) that outputs the first AC voltage (V21) to one end of an external load (4), with a predetermined voltage applied to one end and the other end connected to the first input terminal of the differential amplifier, and a first resistor (R1) connected to the first input terminal of the differential amplifier at one end and to the output terminal of the differential amplifier at the other end, and a second resistor (R2) connected to the first input terminal of the differential amplifier at one end and to the output terminal of the differential amplifier at the other end, and a reference voltage generation circuit (3) that receives the first AC signal (V11) at the second input terminal of the differential amplifier and outputs the first AC voltage (V21) from the output terminal of the differential amplifier, and a voltage-current conversion circuit (2) that is connected to the other end of the external load (4) and supplies an AC current (I) of constant amplitude to the external load from the second AC signal (V12, V2), and a comparator (7) that is connected across the external load (4) and compares the first AC voltage (V21) at one end of the external load with the second AC voltage (V22) at the other end of the external load, and changes the output voltage (V23) when the first AC voltage (V21) and the second AC voltage (V22) are reversed. The control circuit (11, 9) calculates the phase adjustment amount of the second AC signal (V12) with respect to the first AC signal (V11) so that the first AC voltage (V21) and the second AC voltage (V22) are in opposite phase based on the change in the output voltage (V23) from the comparator (7).

As described above, according to the present disclosure, it is not necessary to perform phase adjustment multiple times to find the optimal phase adjustment amount. In other words, by flowing current to the external load only once, the phase adjustment amount (optimal setting) can be found, thereby reducing the man-hours required for phase adjustment. Since automatic adjustment is possible, it can also respond to changes in load characteristics over time. Since the phase adjustment amount is calculated from the point where the voltages V22 and V21 across the load are reversed (zero-cross), the phase adjustment amount can be calculated even if the current is flowed to the load in a state where the phase adjustment is insufficient and the voltage amplitude of V22 is large and clips to the power supply or ground.

Although the invention made by the present inventor has been specifically described based on the embodiment, the present invention is not limited to the embodiment described above, and it is needless to say that various modifications can be made without departing from the gist thereof.

What is claimed is:

1. A drive circuit comprising:
an AC signal source circuit configured to generate AC signal;
a control circuit configured to control the AC signal source circuit to provide a first AC signal and a second AC signal;
a reference voltage generation circuit configured to supply a first drive signal having a constant amplitude AC voltage, based on the first AC signal to a first node of an external load element;
a voltage-to-current conversion circuit configured to supply a second drive signal having a constant amplitude AC current, based on the second AC signal to a second node of the external load element; and
a comparator circuit configured to be connected with the first node and the second node of the external load element, and configured to output an output voltage based on a voltage comparison result of the first drive signal supplied from the first node and the second drive signal supplied from the second node,
wherein the control circuit is further configured to adjust a phase of the second AC signal to be reverse phase with respect to the first AC signal, based on the output voltage from the comparator circuit.

2. The drive circuit according to claim 1,
wherein the reference voltage generation circuit comprises:
a differential amplifier circuit configured to generate the first drive voltage based on the first AC signal;
a first resistor coupled between a first input terminal of the differential amplifier circuit and a first voltage supply; and
a second resistor coupled between the first input terminal of the differential amplifier circuit and an output terminal of the differential amplifier,
wherein the differential amplifier circuit is configured to receive the first AC signal at a second terminal, and configured to output the first drive signal from the output terminal.

3. The driving circuit according to claim 1,
wherein the control circuit is configured to store a digital signal pattern in an array,
wherein the AC signal source circuit is configured to generate the first AC signal from the digital signal supplied from the control circuit via a first digital-to-analog converter (DAC) and a first low-pass filter (LPF), and
wherein the AC signal source circuit is further configured to generate the second AC signal from the digital signal from the control circuit via a second digital-to-analog converter (DAC) and a second low-pass filter (LPF).

4. The driving circuit according to claim 1, further comprises:
a phase adjustment circuit configured to adjust phase of the first AC signal and/or second AC signal; and
a counter configured to count a time according to control by the control circuit,
wherein the control circuit configured to obtain the counter value when the output voltage from the comparator circuit changes, and configured to perform the adjustment of phase by controlling the phase adjustment circuit based on the counter value.

5. The driving circuit according to claim 1,
wherein one or both of the first resistor and the second resistor are variable resistors, and
wherein the control circuit controls the resistance value of one or both of the first resistor and the second resistor.
